(19) United States
(12) Patent Application Publication
(10) Pub. No.: US 2005/0218768 A1
(43) Pub. Date: Oct. 6, 2005

(54) Organic electroluminescent apparatus

(75) Inventor: Nobuo Saito, Gifu-shi (JP)

Correspondence Address: MCDERMOTT WILL & EMERY LLP, 600 13TH STREET, N.W., WASHINGTON, DC, 20005-3096, US

(73) Assignee: SANYO ELECTRIC CO., LTD.

(21) Appl. No.: 11/091,468

(22) Filed: Mar. 29, 2005

(30) Foreign Application Priority Data
Mar. 30, 2004 (JP) 2004-101485
Jan. 31, 2005 (JP) 2005-023292

(51) Int. Cl. H05B 33/02

(52) U.S. Cl. 313/112

(57) ABSTRACT

An organic electroluminescent apparatus essentially includes an organic electroluminescent device, a color filter layer and a substrate. The color filter layer is made of four layers, a red color filter layer, a green color filter layer, a blue color filter layer, and a blue-green color filter layer. The color filter layer is formed between the organic EL device and the substrate. The blue-green color filter layer converts white light emitted from a light emitting layer at a color temperature in the range from 3000 K to 4500 K into white light having high purity at a color temperature of 6500 K.

### BACKGROUND OF THE INVENTION

1. Field of the Invention

The present invention relates to an organic electroluminescent apparatus including a plurality of organic electroluminescent devices.

2. Description of the Background Art

In recent years, with the advent of advanced information technology, there has been an increasing need for a thin type display capable of full-color display. Displays using an organic electroluminescent device (hereinafter referred to as “organic EL device”) have actively been researched and developed as such a thin type display. The display using an organic EL device is thin and lightweight and has middle to high efficiency and no viewing angle dependency.

In the organic EL device, electrons and holes are injected into a light emitting portion from an electron injection electrode and a hole injection electrode, respectively. These electrons and holes are recombined in the luminescent center, so that organic molecules are excited and fluorescent light is emitted when the organic molecules are returned from the excited state to the ground state.

It is an advantage of the organic EL device that the device can operate at a low voltage of about 5 V to 20 V. Techniques of making a full-color display using organic EL devices include a filter method, a CCM (Color Conversion Media) method, and a three-color independent luminescence method. According to the filter method, light is colored through color filters for three primary colors (RGB: red, green, and blue) using a white organic EL device as a light source (backlight). According to the CCM method, light is colored through a color conversion layer using a blue organic EL device as a light source. According to the three-color independent luminescence method, three primary color organic EL devices are provided in parallel on a substrate (see, for example, FPD Guidebook, edited and issued by JEITA (Japan Electronics and Information Technology Industries Association), October 2003, pp. 110-111, chart 2-3-3-5). According to the above described filter method, only an organic EL device for a single color is necessary, and therefore the process of manufacturing the display is advantageously uncomplicated.

However, light emitted from the organic EL device according to the filter method is attenuated as it passes through the three primary color filters. When white is expressed using the three primary color filters, the intensities of light in the three primary colors must be adjusted. In this case, the intensity of light in part of the colors is lowered to adjust the colors, and therefore the resulting white light has lowered intensity. Therefore, voltage to be applied to the organic EL device must be increased. This increases the power consumption by the display.

### SUMMARY OF THE INVENTION

It is an objection of the invention to provide an organic electroluminescent apparatus that allows white light to be obtained with reduced power consumption.

An organic electroluminescent apparatus according to the invention includes an organic electroluminescent device having a first color temperature region and emitting white light, a first filter that transmits light in a red wavelength region in light emitted from the organic electroluminescent device, a second filter that transmits light in a green wavelength region in light emitted from the organic electroluminescent device, a third filter that transmits light in a blue wavelength region in light emitted from the organic electroluminescent device, and a fourth filter that transmits light in a second color temperature region different from the first color temperature region.

In the organic electroluminescent apparatus according to the invention, an organic electroluminescent device emits white light having a first color temperature region. In the emitted light, light in a red wavelength region is transmitted through the first filter, light in a green wavelength region is transmitted through the second filter, light in a blue wavelength region is transmitted through the third filter, and light in a second color temperature region different from the first color temperature region is transmitted through the fourth filter. In this way, light in the red, green, and blue wavelength regions and light in the second color temperature region can be obtained.

Light in the second color temperature region is less attenuated than the case of obtaining light in the second color temperature region by mixing and adjusting light in the red, green, and blue wave length regions. Consequently, high voltage does not have to be applied to the organic electroluminescent device, and white light can be obtained with reduced power consumption in the organic electroluminescent apparatus.

The first filter preferably has a transmittance of at least 70% in a wavelength region of at least 600 nm, the second filter preferably has a transmittance of at least 70% in a wavelength region of not less than 495 nm and not more than 555 nm, and the third filter preferably has a transmittance of at least 70% in a wavelength region of at most 495 nm.

The first filter preferably has a transmittance of at most 10% in a wavelength region of at most 575 nm, the second filter preferably has a transmittance of at most 10% in a wavelength region of at most 470 nm and a transmittance of at most 10% in a wavelength region of at least 605 nm, the third filter preferably has a transmittance of at most 10% in a wavelength region of at least 550 nm. In this way, red light, green light, and blue light each having high purity can be transmitted through the first, second, and third filters, respectively.

The fourth filter preferably has a transmittance of at least 70% in a wavelength region not less than 435 nm and not more than 520 nm. In this way, light in the second color temperature region having high purity can be transmitted through the fourth filter.

The fourth filter preferably has a transmittance of not less than 45% and not more than 75% in a wavelength region of more than 520 nm and at most 560 nm. In this way, light in the second color temperature region having high purity can be transmitted through the fourth filter.

The fourth filter preferably has a transmittance of not less than 25% and not more than 60% in a wavelength region of more than 560 nm and at most 610 nm. In this way, light in the second color temperature region having high purity can be transmitted through the fourth filter.

The fourth filter preferably has a transmittance of not less than 5% and not more than 35% in a wavelength region of more than 610 nm and at most 640 nm. In this way, light in the second color temperature region having high purity can be transmitted through the fourth filter.

The fourth filter preferably has a transmittance of at most 10% in a wavelength region of more than 640 nm. In this way, light in the second color temperature region having high purity can be transmitted through the fourth filter.

The fourth filter preferably has a transmittance of not less than 45% and not more than 75% in a wavelength region of at least 410 nm and less than 435 nm. In this way, light in the second color temperature region having high purity can be transmitted through the fourth filter.

The fourth filter preferably has a transmittance of not less than 30% and not more than 60% in a wavelength region of at least 400 nm and less than 410 nm.

The first color temperature region preferably corresponds to the color temperature range from 3000 K to 4500 K. In this way, the organic electroluminescent device can emit white light. Therefore, white light emitted from the organic electroluminescent device can be used as a light source (backlight) for the organic electroluminescent apparatus.

The second color temperature region preferably corresponds to the color temperature range from 4500 K to 8500 K. In this way, the fourth filter can convert white light emitted from the organic electroluminescent device into white light with high purity.

The second color temperature region more preferably corresponds to the color temperature range from 5500 K to 7500 K. In this way, the fourth filter can convert white light emitted from the organic electroluminescent device into white light with higher purity.

The second color temperature region even more preferably corresponds to the color temperature range from 6000 K to 7000 K. In this way, the fourth filter can convert white light emitted from the organic electroluminescent device into white light with even higher purity.

The third and fourth filters preferably have a transmittance of at most 30% in a wavelength region of less than 400 nm. In this way, functional degradations of the organic layers caused by ultraviolet radiation can be prevented.

According to the invention, the use of the first to fourth filters allows white light to be obtained with reduced power consumption.

The foregoing and other objects, features, aspects, and advantages of the present invention will become more apparent from the following detailed description of the present invention when taken in conjunction with the accompanying drawings.

### BRIEF DESCRIPTION OF THE DRAWINGS

FIG. 1 is a schematic view of an organic EL apparatus according to an embodiment of the invention;

FIG. 2 is a detailed sectional view of the structure of the organic EL apparatus in FIG. 1;

FIG. 3 is a view for use in illustration of a color filter layer according to the embodiment;

FIG. 4 is a CIE chromaticity diagram; and

FIGS. 5 to 8 are graphs showing the wavelength-transmittance characteristics for red, green, blue, and blue-green color filter layers, respectively.

### DESCRIPTION OF THE PREFERRED EMBODIMENTS

Now, an organic electroluminescent (hereinafter referred to as “organic EL”) apparatus according to the invention will be described.

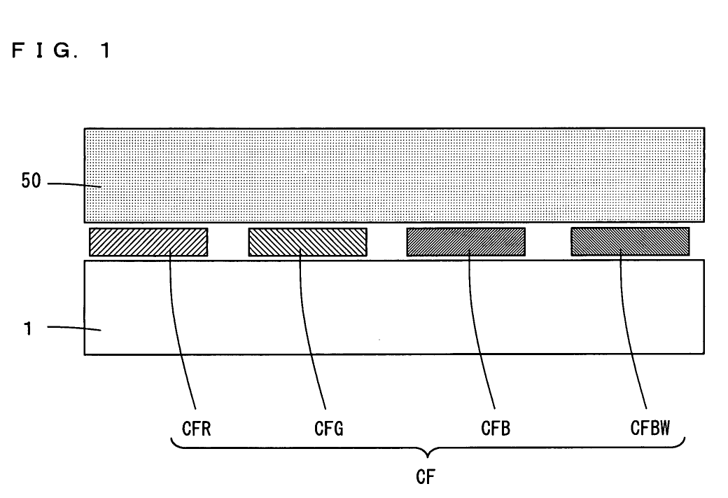

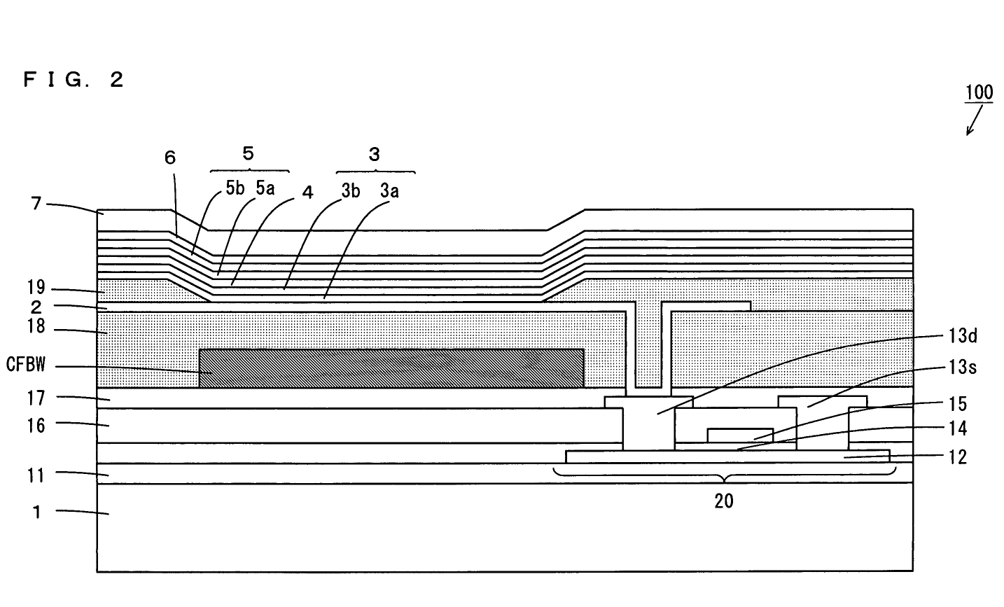

FIG. 1 is a schematic sectional view of an organic EL apparatus according to an embodiment of the invention, and FIG. 2 is a detailed sectional view of the structure of the organic EL apparatus in FIG. 1.

As shown in FIG. 1, the organic EL apparatus according to the embodiment essentially includes an organic EL device 50, a color filter layer CF, and a substrate 1. The color filter layer CF includes four layers, a red color filter layer CFR, a green color filter layer CFG, a blue color filter layer CFB, and a blue-green color filter layer CFBW.

As shown in FIG. 1, the color filter layer CF is formed between the organic EL device 50 and the substrate 1. In the color filter layer CF, the adjacent four layers, the red color filter layer CFR, the green color filter layer CFG, the blue color filter layer CFB, and the blue-green color filter layer CFBW form one pixel. The color filter layer CF will be detailed later.

Now, the structure of the organic EL apparatus in FIG. 1 will be described with reference to FIG. 2. As shown in FIG. 2, a layered film 11 having for example a layer of silicon oxide (SiO₂) and a layer of silicon nitride (SiNx) is formed on a transparent substrate 1 of a material such as glass and plastic.

A TFT (Thin Film Transistor) 20 is formed on a part of the layered film 11. The TFT 20 includes polycrystalline silicon 12, a source electrode 13s, a drain electrode 13d, a gate oxide film 14, and a gate electrode 15.

The drain electrode 13d and the source electrode 13s are formed on the polycrystalline silicon 12. The drain electrode 13d of the TFT 20 is connected to a hole injection electrode 2 (that will be described), and the source electrode 13s of the TFT 20 is connected to a power supply line (not shown).

A first interlayer insulating film 16 is formed on the gate oxide film 14 to cover the gate electrode 15. A second interlayer insulating film 17 is formed on the first interlayer insulating film 16 to cover the drain electrode 13d and the source electrode 13s.

A color filter layer CF is formed on the second interlayer insulating film 17. As described above, the color filter layer CF includes the red color filter layer CFR, the green color filter layer CFG, the blue color filter layer CFB, and the blue-green color filter layer CFBW. FIG. 2 shows the blue-green color filter layer CFBW that is one of the layers in the color filter layer CF by way of illustration.

The red color filter layer CFR transmits light in a wavelength region for red, the green color filter layer CFG transmits light in a wavelength region for green, the blue color filter layer CFB transmits light in a wavelength region for blue, and the blue-green color filter layer CFBW transmits light in a wavelength region for white.

The red color filter layer CFR preferably has a transmittance of at least 70% in the wavelength range of 600 nm or more, the green color filter layer CFG preferably has a transmittance of at least 70% in the wavelength range from 495 nm to 555 nm, and the blue color filter layer CFB preferably has a transmittance of at least 70% in the wavelength range of 495 nm or less.

The blue color filter layer CFB preferably has a transmittance of at most 30% in the wavelength range less than 400 nm so that less ultraviolet light is transmitted.

The red color filter CFR preferably has a transmittance of at most 10% in the wavelength range of 575 nm or less. The green color filter layer CFG preferably has a transmittance of at most 10% in the wavelength range of 470 nm or less and a transmittance of at most 10% in the wavelength range of 605 nm or more. The blue color filter layer CFB preferably has a transmittance of at most 10% in the wavelength range of 550 nm or more. In this way, the red color filter layer CFR, the green color filter layer CFG, and the blue color filter layer CFB can transmit red light, green light, and blue light each having high purity, respectively.

The blue-green color filter layer CFBW preferably has a transmittance of at most 30% in the wavelength range of less than 400 nm so that less ultraviolet light is transmitted.

The transmittance of the blue-green color filter layer CFBW is preferably least 70% in the wavelength range from 435 nm to 520 nm, from 45% to 75% in the wavelength range of more than 520 nm and not more than 560 nm, from 25% to 60% in the wavelength range of more than 560 nm and not more than 640 nm, from 5% to 35% in the wavelength range more than 610 nm and not more than 640 nm, at most 10% in the wavelength range more than 640 nm, from 45% to 75% in the wavelength range of not less than 410 nm and less than 435 nm, and from 30% to 60% in the wavelength range of not less than 400 nm and less than 410 nm. In this way, the blue-green color filter layer CFBW can transmit white light having high purity.

The transmittance characteristic of the color filter layers described above can be achieved by adjusting the contents of existing dyes in the type of color filter that uses dyes, and by adjusting the dispersion of existing pigments in the type of color filter that uses pigments.

In the blue color filter layer CFB and the blue-green color filter layer CFBW, an ultraviolet absorber may be provided in addition to the pigments or dyes, so that the transmittance is not more than 30% in the wavelength range of less than 400 nm and ultraviolet light is absorbed. Note that also in the red and green color filter layers CFR and CFG, an ultraviolet absorber may be added if necessary, so that the transmittance can surely be not more than 30% in the wavelength range of less than 400 nm. In this way, ultraviolet radiation is absorbed by all the color filters, so that functional degradations of the organic layer (such as degradations in the luminous efficiency and the useful luminous life) caused by ultraviolet radiation can be reduced.

A first flattening layer 18 for example of acrylic resin is formed on the second interlayer insulating film 17 to cover the color filter layer CF. A transparent hole injection electrode 2 is formed for each pixel on the first flattening layer 18, and an insulating, second flattening layer 19 is formed in the region between pixels to cover the hole injection electrode 2. Note that the hole injection electrode 2 is made of a transparent conductive film for example of indium-tin-oxide (ITO).

A hole injection layer 3 is formed to cover the hole injection electrode 2 and the second flattening layer 19. The hole injection layer 3 has a layered structure including first and second injection layers 3a and 3b. The first injection layer 3a in the hole injection layer 3 is made for example of copper phthalocyanine (CuPc). The first injection layer 3a is for example as thick as 100 Å. The second injection layer 3b in the hole injection layer 3 is made for example of fluorocarbon (CFx).

A hole transport layer 4, an orange light emitting layer 5a that emits orange light, a blue light emitting layer 5b that emits blue light, and an electron transport layer 6 are sequentially formed on the hole injection layer 3. Then, an electron injection electrode 7 of a material such as fluorolithium (LiF) and aluminum (Al) is formed on the electron transport layer 6.

The hole transport layer 4 is made of an organic material such as N,N′-Di(naphthalene-1-yl)-N,N′-diphenyl-benzidine (hereinafter abbreviated as “NPB”) represented by the following formula (1). The hole transport layer 4 is for example as thick as 2400 Å.

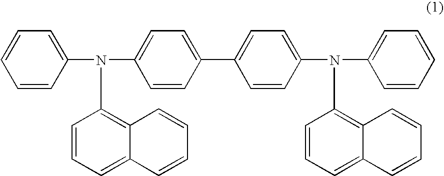

The orange light emitting layer 5a is made for example of NPB represented by the formula (1) as a host material, 5,12-Bis(4-tert-butylphenyl)-naphthacene (hereinafter abbreviated as tBuDPN) represented by the formula (2) as a first light emitting dopant, and 5,12-Bis(4-(6-methylbenzothiazol-2-yl)phenyl)-6,11-dipheny lnaphthacene (hereinafter abbreviated as DBzR) represented by the formula (3) as a second light emitting dopant. The orange light emitting layer 5a is for example as thick as 300 Å. The color temperature of white light emitted from the light emitting layer 5 is in the range from 3000 K to 4500 K.

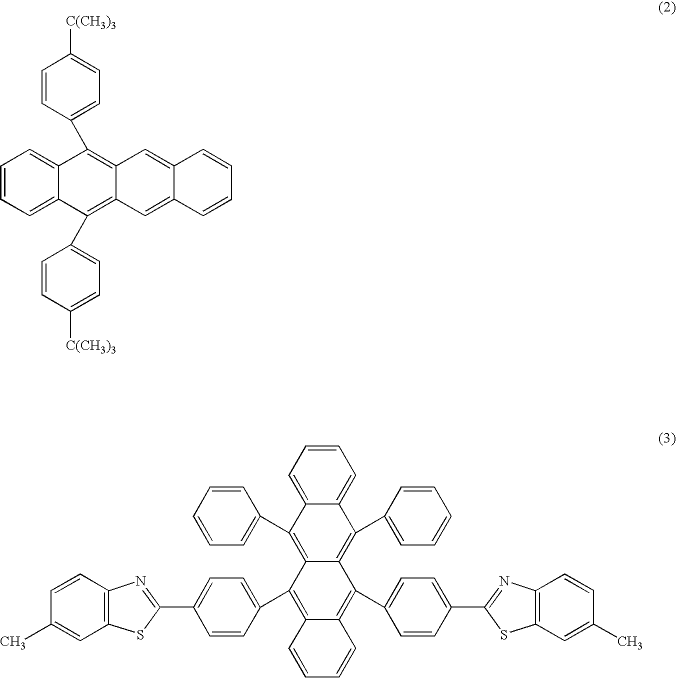

Note that the orange light emitting layer 5a is doped with 20.0 wt % of tBuDPN represented by the formula (2) as the first dopant, for example, and doped with 3.0 wt % of DBzR represented by the formula (3) as the second dopant, for example.

The blue light emitting layer 5b is made for example of tertiary-butyl substituted dinaphthyl anthracene (hereinafter abbreviated as “TBADN”) represented by the formula (4) as a host material, NPB represented by the formula (1) as a first dopant, and 1,4,7,10-tetra-tert-butylperylene (hereinafter abbreviated as “TBP”) represented by the formula (5) as a second dopant. The blue light emitting layer 5b is about as thick as 400 Å.

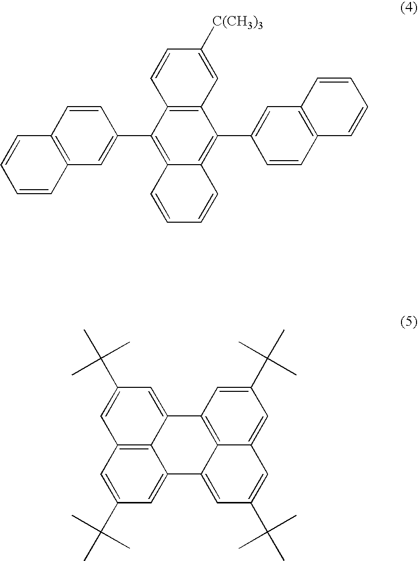

Note that the blue light emitting layer 5b is doped with 7.5 wt % of NPB represented by the formula (1) as the first dopant, for example, and doped with 2.5 wt % of TBP represented by the formula (5) as the second dopant, for example.

The orange light emitting layer 5a and the blue light emitting layer 5b (hereinafter simply as “light emitting layer 5”) emit white light having a intensity peak in each of the wavelength ranges from 460 nm to 510 nm and from 550 nm to 640 nm.

The electron transport layer 6 is made for example of Tris(8-hydroxyquinolinato)aluminum (hereinafter abbreviated as “Alq”) represented by the following formula (6). The electron transport layer 6 is for example as thick as 100 Å.

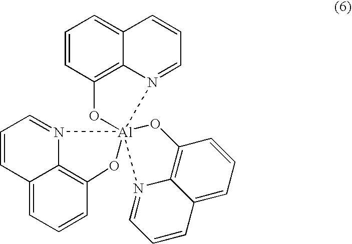

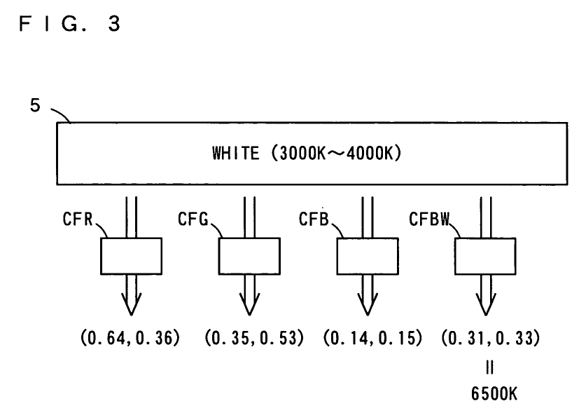

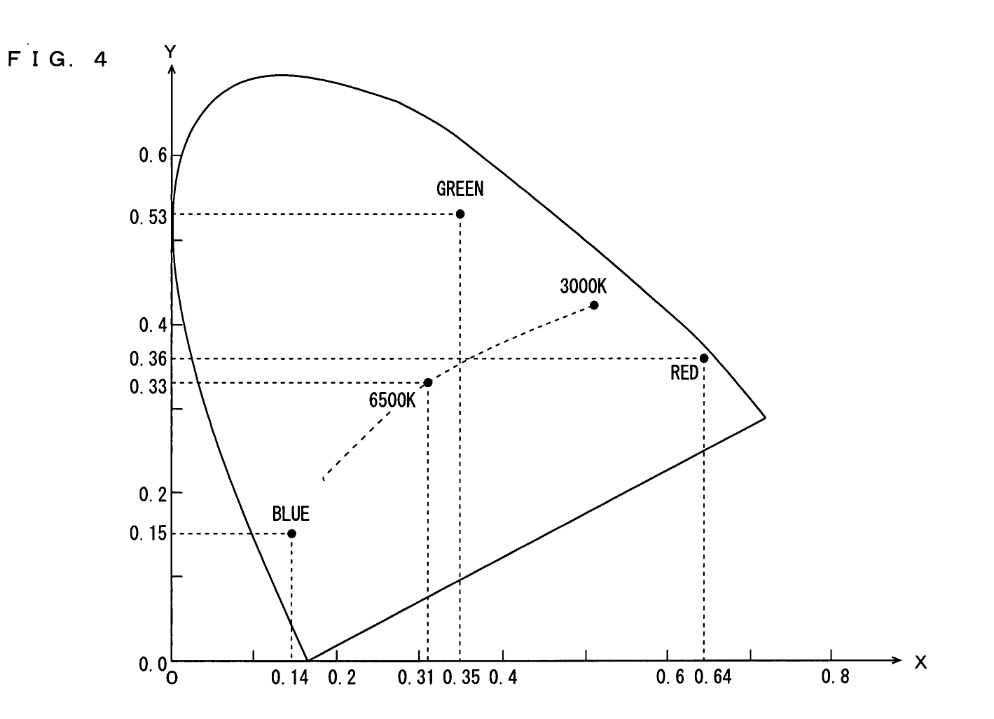

FIG. 3 is a view for use in illustration of a color filter layer CF according to the embodiment, and FIG. 4 is a CIE chromaticity diagram.

As shown in FIG. 3, a red color filter layer CFR, a green color filter layer CFG, a blue color filter layer CFB, and a blue-green color filter layer CFBW are provided opposing the light emitting layer 5.

Note that light emitting layer 5 emits white light having a color temperature in the range from 3000 K to 4500 K. As shown in FIG. 4, light having a color temperature of 3000 K is white light close to red light rather than white light having high purity. To obtain white light having high purity, the color temperature is preferably in the range from 4500 K to 8500 K, more preferably from 5500 K to 7500 K, even more preferably from 6000 K to 7000 K, most preferably 6500 K.

Light emitted from the light emitting layer 5 is converted into red light as it is transmitted through the red color filter layer CFR. Similarly, the light emitted from the light emitting layer 5 is converted into green light and blue light as it is transmitted through the green color filter layer CFG and the blue color filter layer CFB, respectively. The light emitted from the light emitting layer 5 is converted into white light as it is transmitted through the blue-green color filter layer CFBW.

As shown in FIG. 4, the red light is represented by the CIE chromaticity coordinates (0.64, 0.36), the green light by the CIE chromaticity coordinates (0.35, 0.53), the blue light by the CIE chromaticity coordinates (0.14, 0.15), and the white light by the CIE chromaticity coordinates (0.31, 0.33). The color temperature of the white light represented by the CIE chromaticity coordinates (0.31, 0.33) is 6500 K.

Now, the blue-green color filter layer CFBW will be described. The blue-green color filter layer CFBW converts white light at a color temperature in the range from 3000 K to 4500 K at the light emitting layer 5 into highly pure white light at a color temperature of 6500 K. The blue light is generally known to have high color temperature. Therefore, the blue-green color filter layer CFBW transmits blue light most. Therefore, white light at a color temperature in the range from 3000 K to 4500 K at the light emitting layer 5 is converted into highly pure white light at a color temperature of 6500 K as it is transmitted through the blue-green color filter layer CFBW.

As in the foregoing, in the organic electroluminescent apparatus according to the embodiment, full-color display is made using the red color filter layer CFR, the green color filter layer CFG, the blue color filter layer CFB, and the blue-green color filter layer CFBW, and white light having high purity can be obtained using the blue-green color filter layer CFBW. Therefore, white light can be obtained with lower power consumption than the case of mixing and adjusting red light, green light, and blue light to obtain white light having high purity. Consequently, white light can be obtained with reduced power consumption in the organic electroluminescent apparatus.

According to the embodiment, the red color filter layer CFR corresponds to the first filter, the green color filter layer CFG corresponds to the second filter, the blue color filter layer CFB corresponds to the third filter, and the light emitting layer 5 (the orange light emitting layer 5a and the blue light emitting layer 5b) corresponds to the light emitting layer.

### EXAMPLES

In the following example, an organic EL apparatus according to the embodiment was evaluated.

### Inventive Example

In this example, a red color filter layer CFR, a green color filter layer CFG, a blue color filter layer CFB, and a blue-green color filter layer CFBW having the following characteristics were used.

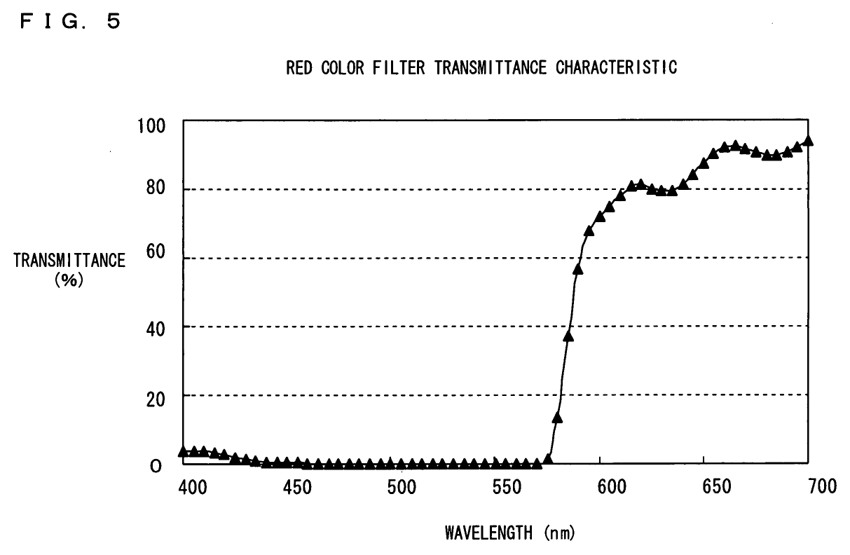

FIGS. 5 to 8 are graphs showing the wavelength-transmittance characteristics for the red color filter layer CFR, the green color filter layer CFG, the blue color filter layer CFB, and the blue-green color filter layer CFBW, respectively. In the graphs in FIGS. 5 to 8, theordinate represents the transmittance and the abscissa represents the wavelength.

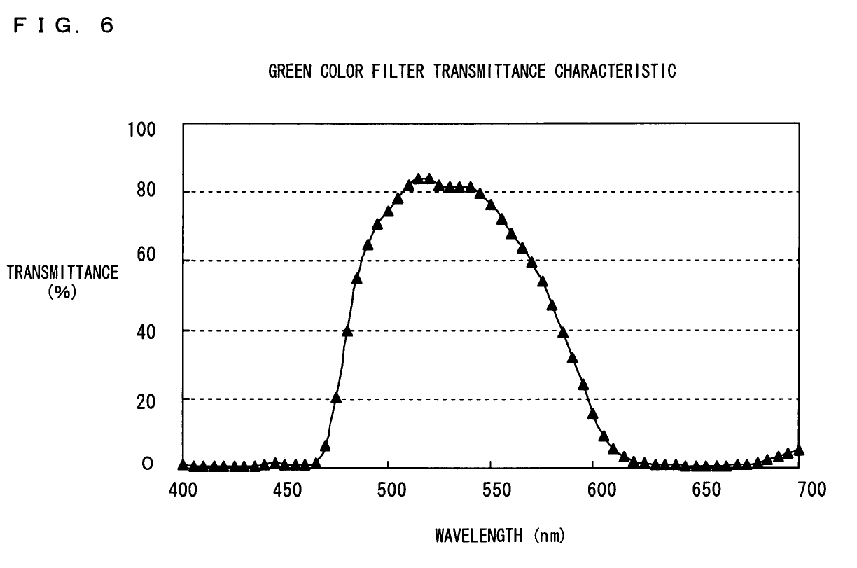

As shown in FIG. 5, the red color filter layer CFR has a transmittance of at least 70% in the wavelength range of 600 nm or more. As shown in FIG. 6, the green color filter layer CFG has a transmittance of at least 70% in the wavelength range from 495 nm to 555 nm.

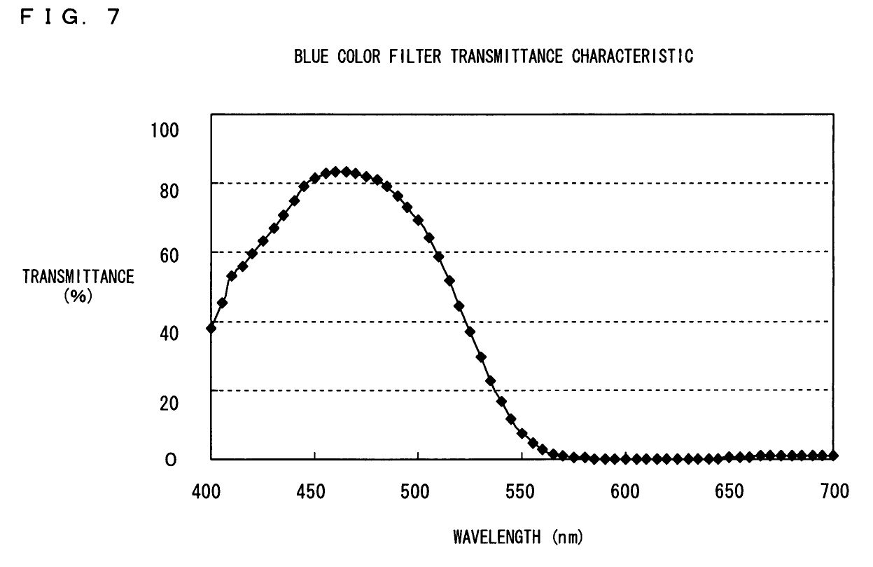

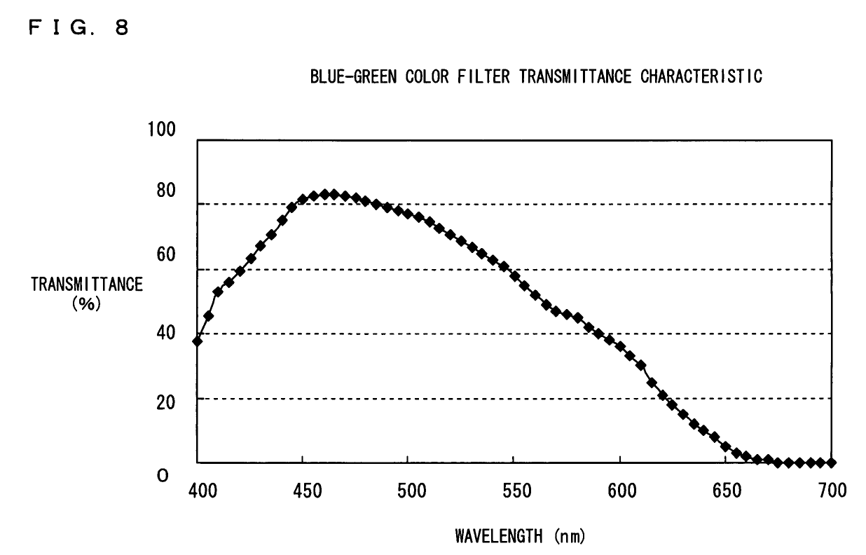

As shown in FIG. 7, the blue color filter layer CFB has a transmittance of at least 70% in the wavelength range of 495 nm or less. As shown in FIG. 8, the blue-green color filter layer CFBW has a transmittance of at least 70% in the wavelength range from 435 nm to 520 nm.

Comparative Example

In a comparative example, the blue-green color filter layer CFBW in the embodiment was not used, and the red color filter layer CFR, the green color filter layer CFG, and the blue color filter layer CFB were used.

Evaluation

In the organic EL apparatus according to the inventive example, the chromaticity and luminous efficiency were measured for red light, green light, and blue light, and the chromaticity, luminous efficiency, and power consumption were measured for white light having high purity. In the organic EL apparatus according to the comparative example, red light, green light, and blue light were mixed and adjusted to obtain white light having high purity at a color temperature of 6500 K and the power consumption was measured.

When red light was obtained using the organic EL apparatus according to the inventive example, the chromaticity of the red light passed through the red color filter layer CFR was represented by the CIE chromaticity coordinates (0.64, 0.36), and the luminous efficiency was 3.0 cd/A.

When green light was obtained using the organic EL apparatus according to the inventive example, the chromaticity of the green light passed through the green color filter layer CFG was represented by the CIE chromaticity coordinates (0.35, 0.53), and the luminous efficiency was 6.5 cd/A.

When blue light was obtained using the organic EL apparatus according to the inventive example, the chromaticity of the blue light passed through the blue color filter layer CFB was represented by the CIE chromaticity coordinates (0.14, 0.15), and the luminous efficiency was 1.5 cd/A.

When white light having high purity was obtained using the organic EL apparatus according to the inventive example, the chromaticity of the white light passed through the blue-green color filter layer CFBW was represented by the CIE chromaticity coordinates (0.31, 0.33), and the luminous efficiency was 10 cd/A.

The power consumed by obtaining white light having high purity at a color temperature of 6500 K using the organic EL apparatus according to the inventive example was 0.6 times the power consumed by obtaining white light having high purity at a color temperature of 6500 K using the organic EL apparatus according to the comparative example. Consequently, it has been found that white light can be obtained with reduced power consumption by using the blue-green color filter layer CFBW.

Note that the ultraviolet absorbing function of the color filter layers may be achieved using another layer. For example, a first flattening layer 18 (of an acrylic material) as a separately provided transparent film on all the color filter layers may include an ultraviolet absorber. In this case, the layered structure consisting of the color filters and the first flattening layer provides the color filtering function.

Although the present invention has been described and illustrated in detail, it is clearly understood that the same is by way of illustration and example only and is not to be taken by way of limitation, the spirit and scope of the present invention being limited only by the terms of the appended claims.

1. An organic electroluminescent apparatus, comprising:
an organic electroluminescent device having a first color temperature region and emitting white light;
a first filter that transmits light in a red wavelength region in light emitted from said organic electroluminescent device;
a second filter that transmits light in a green wavelength region in light emitted from said organic electroluminescent device;
a third filter that transmits light in a blue wavelength region in light emitted from said organic electroluminescent device; and
a fourth filter that transmits light in a second color temperature region different from said first color temperature region.

2. The organic electroluminescent apparatus according to claim 1, wherein
said fourth filter has a transmittance of at least 70% in a wavelength range not less than 435 nm and not more than 520 nm.

3. The organic electroluminescent apparatus according to claim 1, wherein
said fourth filter has a transmittance of not less than 45% and not more than 75% in a wavelength range more than 520 nm and at most 560 nm.

4. The organic electroluminescent apparatus according to claim 1, wherein
said fourth filter has a transmittance of not less than 25% and not more than 60% in a wavelength range more than 560 nm and at most 610 nm.

5. The organic electroluminescent apparatus according to claim 1, wherein
said fourth filter has a transmittance of not less than 5% and not more than 35% in a wavelength range more than 610 nm and at most 640 nm.

6. The organic electroluminescent apparatus according to claim 1, wherein
said fourth filter has a transmittance of at most 10% in a wavelength range more than 640 nm.

7. The organic electroluminescent apparatus according to claim 1, wherein
said fourth filter has a transmittance of not less than 45% and not more than 75% in a wavelength range not less than 410 nm and less than 435 nm.

8. The organic electroluminescent apparatus according to claim 1, wherein
said fourth filter has a transmittance of not less than 30% and not more than 60% to in a wavelength range at least 400 nm and less than 410 nm.

9. The organic electroluminescent apparatus according to claim 1, wherein
said first color temperature region corresponds to the color temperature range from 3000 K to 4500 K.

10. The organic electroluminescent apparatus according to claim 1, wherein
said second color temperature region corresponds to the color temperature range from 4500 K to 8500 K.

11. The organic electroluminescent apparatus according to claim 1, wherein
said second color temperature region corresponds to the color temperature range from 5500 K to 7500 K.

12. The organic electroluminescent apparatus according to claim 1, wherein
said second color temperature region corresponds to the color temperature range from 6000 K to 7000 K.

13. The organic electroluminescent apparatus according to claim 1, wherein
said first filter has a transmittance of at least 70% in a wavelength range not less than 600 nm.

14. The organic electroluminescent apparatus according to claim 1, wherein
said second filter has a transmittance of at least 70% in a wavelength range not less than 495 nm and not more than 555 nm.

15. The organic electroluminescent apparatus according to claim 1, wherein
said third filter has a transmittance of at least 70% in a wavelength range not more than 495 nm.

16. The organic electroluminescent apparatus according to claim 1, wherein
said first filter has a transmittance of at most 10% in a wavelength range not more than 575 nm.

17. The organic electroluminescent apparatus according to claim 1, wherein
said second filter has a transmittance of at most 10% in a wavelength range not more than 470 nm, and has a transmittance of at most 10% in a wavelength range not less than 605 nm.

18. The organic electroluminescent apparatus according to claim 1, wherein
said third filter has a transmittance of at most 10% in a wavelength range not less than 550 nm.

19. The organic electroluminescent apparatus according to claim 1, wherein
said third and fourth filters have a transmittance of at most 30% in a wavelength range less than 400 nm.
